(19) United States
(12) Patent Application Publication
(10) Pub. No.: US 2020/0294440 A1
(43) Pub. Date: Sep. 17, 2020

(54) DISPLAY PANEL AND BOOST CIRCUIT THEREOF

(71) Applicant: AU Optronics Corporation, Hsin-Chu (TW)

(72) Inventors: Wei-Ming CHENG, HSIN-CHU (TW); Min-Hsuan CHIU, HSIN-CHU (TW)

(21) Appl. No.: 16/439,008

(22) Filed: Jun. 12, 2019

(30) Foreign Application Priority Data
Mar. 13, 2019 (TW) 108108505

(51) Int. Cl. G09G 3/20; H03K 17/687

(52) U.S. Cl. CPC G09G 3/2092; G09G 2330/02; H03K 17/6871

(57) ABSTRACT

A display panel includes a boost circuit and a pixel circuit. The boost circuit is configured to receive a data voltage and generate a driving voltage according to the data voltage. The voltage value of the driving voltage is greater than the voltage value of the data voltage. The pixel circuit is electrically connected to the boost circuit for receiving the driving voltage.

### CROSS-REFERENCE TO RELATED APPLICATION

This application claims priority to Taiwan Application Serial Number 108108505, filed Mar. 13, 2019, which is herein incorporated by reference in its entirety.

### BACKGROUND

### Technical Field

The present disclosure relates to a display panel and boost circuit thereof, especially a technology that drives the pixel circuit according to the data voltage from the data line.

### Description of Related Art

With the development of display technology, the display panel is widely used in daily lives of people and as an increasingly important role. For example, the display panel can be used in various electronic devices such as televisions, computers, mobile phones to present various information.

In general, the display panel will provide a corresponding voltage to the internal pixel circuit according to the image signal, and displays the desired brightness or color. This driving process that supplies voltage to the pixel circuit will directly affect the display quality of the display panel.

### SUMMARY

One aspect of the present disclosure is a display panel. The display panel includes a boost circuit and a pixel circuit. The boost circuit is configured to receive a data voltage, and configured to generate a driving voltage according to the data voltage. A voltage value of the driving voltage is greater than a voltage value of the data voltage. The pixel circuit is electrically connected to the boost circuit to receive the driving voltage.

Another aspect of the present disclosure is a boost circuit. The boost circuit includes a first switching circuit, a first capacitor and a second switching circuit. The first switching circuit is electrically connected to a data line and a pixel circuit to receive a data voltage. A first terminal of the first capacitor is electrically connected to the first switching circuit. The second switching circuit is electrically connected to the data line and a second terminal of the first capacitor to generate a driving voltage according to the data voltage. A voltage value of the driving voltage is greater than a voltage value of the data voltage.

It is to be understood that both the foregoing general description and the following detailed description are by examples, and are intended to provide further explanation of the disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic diagram of a display panel in some embodiments of the present disclosure.

FIG. 2 a waveform diagram of a display panel in some embodiments of the present disclosure.

FIG. 3A is an operation schematic diagram of a boost circuit in some embodiments of the present disclosure.

FIG. 3B is an operation schematic diagram of a boost circuit in some embodiments of the present disclosure.

FIG. 4 is a schematic diagram of a driving signal in some embodiments of the present disclosure.

### DETAILED DESCRIPTION

For the embodiment below is described in detail with the accompanying drawings, embodiments are not provided to limit the scope of the present disclosure. Moreover, the operation of the described structure is not for limiting the order of implementation. Any device with equivalent functions that is produced from a structure formed by a recombination of elements is all covered by the scope of the present disclosure. Drawings are for the purpose of illustration only, and not plotted in accordance with the original size.

It will be understood that when an element is referred to as being “connected to” or “coupled to”, it can be directly connected or coupled to the other element or intervening elements may be present. In contrast, when an element to another element is referred to as being “directly connected” or “directly coupled,” there are no intervening elements present. As used herein, the term “and/or” includes an associated listed items or any and all combinations of more.

With the improvement of display technology, consumers are paying more and more attention to the display quality and performance of the display panel. For example, the high frame rate pictures required in e-Sports games (e.g., 240 Hz, 320 Hz) will cause differences in the performance of the display panel.

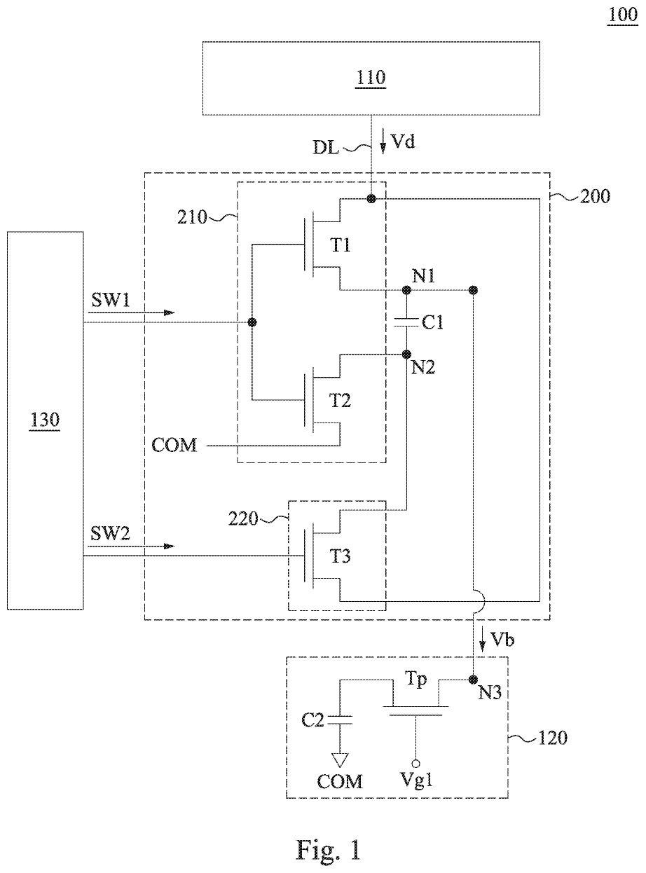

The present disclosure relates to a display panel 100 and a boost circuit 200. Refer to FIG. 1, which is a schematic diagram of the display panel 100 according to some embodiments of the present disclosure. The display panel 100 includes a boost circuit 200 and a pixel circuit 120. The pixel circuit 120 includes multiple pixel units. For convenience of explanation of the present disclosure, only one pixel unit is shown in FIG. 1. Since the person in the art can understand the structure and driving principle of the pixel unit, it will not be described here.

The boost circuit 200 is configured to receive a data voltage Vd through a data line DL. The boost circuit 200 is further configured to perform a boosting process according to the data voltage Vd to generate a driving voltage Vb.

The voltage value of the driving voltage Vb is greater than a voltage value of the data voltage Vb. The pixel circuit 120 is electrically connected to the boost circuit 200 so as to receive the driving voltage Vb.

Accordingly, the data voltage Vd transmitted by the data line DL is processed by the boost circuit 200, and is boosted to the driving voltage Vb, and then the pixel circuit 120 is driven. Therefore, the pixel circuit 120 will be driven faster, and the transmittance of the pixel unit may be improved. Taking the display panel of the liquid crystal screen as an example, the liquid crystal in the pixel circuit 120 can be driven faster by the boost circuit 200, and the response time is controlled between 4 and 5 milliseconds.

In some embodiments, the boost circuit 200 stores the data voltage Vd according to a first switching signal SW1, and generates the driving voltage Vb according to a second switching signal SW2. For example, the boost circuit 200 includes a first capacitor C1. When the boost circuit 200 receives the first switching signal SW1, the first terminal N1 of the first capacitor C1 will receive the data voltage Vb for charging. When the boost circuit 200 receives the second switching signal SW2, the second terminal N2 of the first capacitor C1 also receives the data voltage Vb. At this time, according to the energy conservation law, the voltage difference between the two terminals of the first capacitor C1 should be balanced, so the voltage value of the first terminal N1 of the first capacitor C1 will be doubled to the data voltage Vd, and formed the driving voltage Vb.

In some embodiments, the display panel 100 further includes a source driver 110 and a gate driver 130. The source driver 110 is configured to transmit the data voltage Vd through the data line DL. The gate driver 130 is configured to provide the first switching signal SW1 and the second switching signal SW2.

For convenience of understanding, here explaining the structure of the boost circuit 200. As shown in FIG. 1, In some embodiments, the boost circuit 200 includes a first switching circuit 210, a first capacitor C1, and a second switching circuit 220. The first switching circuit 210 is electrically connected to the data line DL and the pixel circuit 120 so as to receive the data voltage Vd. The first terminal N1 of the first capacitor C1 is electrically connected to the first switching circuit 210. The second switching circuit 220 is electrically connected to the data line DL and the second terminal N2 of the first capacitor C1 so as to receive the driving voltage Vb according to the data voltage Vd.

In some embodiments, the first switching circuit 210 is turned on or off according to the first switching signal SW1 and the power supply voltage COM to transmit the data voltage Vd from the data line DL to the pixel circuit 120. For example, when the first switching signal SW1 is at a high level and the power supply voltage COM is at a low level, the first switching circuit 210 is turned on. The second switching circuit 220 is turned on or off according to the second switching signal SW2 to generate the driving voltage Vb at the first terminal N1 of the first capacitor C1 according to the data voltage Vd. For example, when the second switching signal SW2 is at a high level, the second switching circuit 220 is turned on.

In some embodiments, the first switching circuit 210 further includes the first transistor switch T1 and the second transistor switch T2. The first terminal of the first transistor switch T1 is electrically connected to the data line DL. The second terminal of the first transistor switch T1 is electrically connected to the first terminal N1 of the first capacitor C1 and the pixel circuit 120. The first terminal of the second transistor switch T2 is electrically connected to the second terminal N2 of the first capacitor C1. The second terminal of the second transistor switch T2 is electrically connected to the power supply terminal, to receive the power supply signal COM.

In some embodiments, the second switching circuit 220 further includes the third transistor switch T3. The first terminal of the third transistor switch T3 is electrically connected to the second terminal N2 of the first capacitor C1. The second terminal of the third transistor switch T3 is electrically connected to the data line DL.

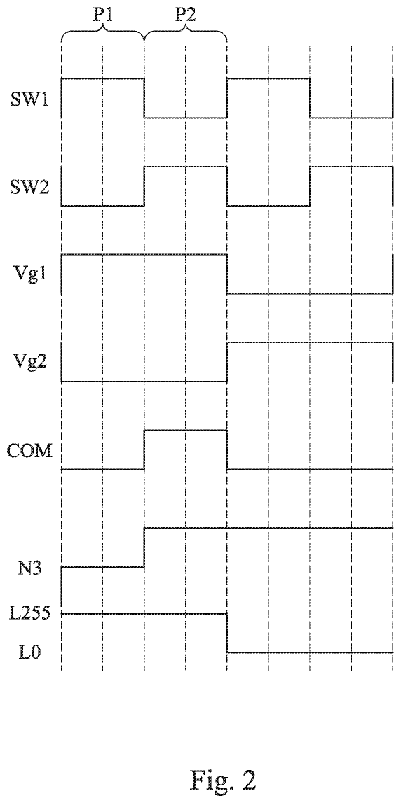

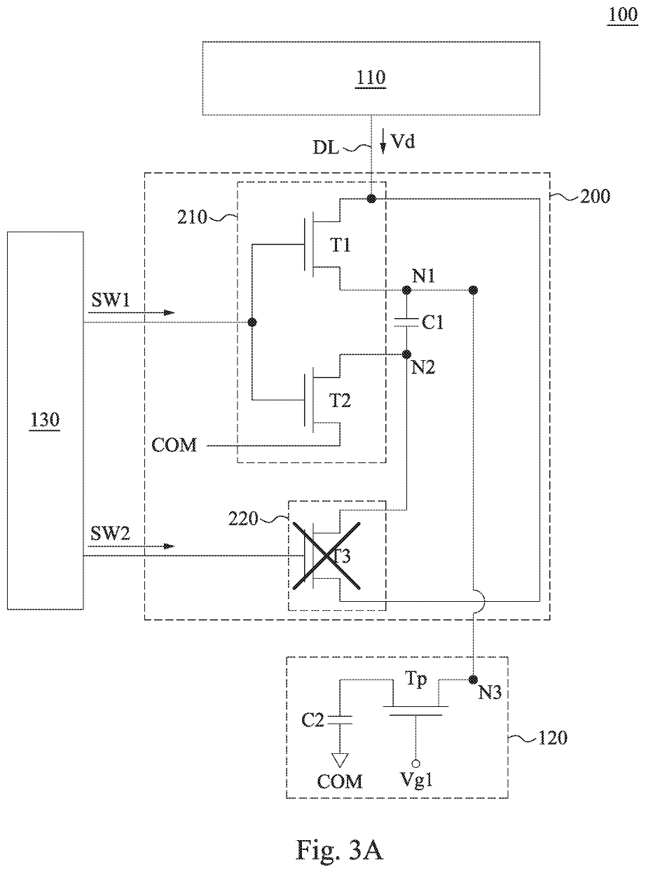

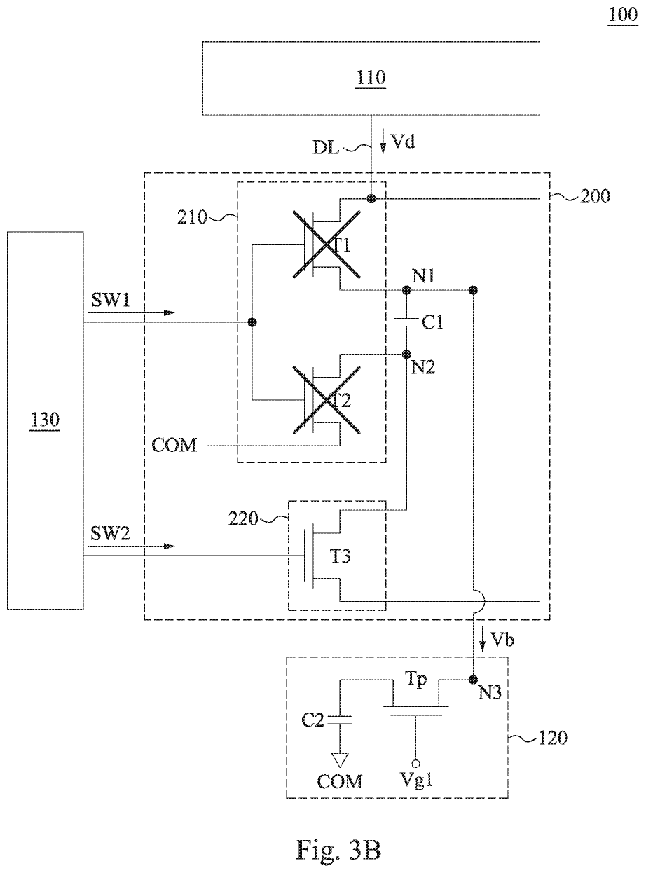

Referring to FIGS. 2-3B, here explaining the operation of the boost circuit 200. FIG. 2 is a waveform diagram of signals of display panel according to some embodiments of the present disclosure. The voltage received by the pixel circuit 120 can be represented by the voltage on node N3. In some embodiments, each pixel unit in the pixel circuit 120 includes the pixel transistor Tp and the second capacitor C2. The pixel circuit 120 must receive the driving voltage Vb and the corresponding gate voltage simultaneously to be turned on to charge the second capacitor C2. “Vg1” in FIG. 2 represents the first gate voltage Vg1 for controlling the first pixel unit (e.g., the pixel transistor Tp shown in FIG. 1). Similarly, Vg2 represents the second gate voltage Vg2 for controlling the second pixel unit.

In some embodiments, the two terminals of the second capacitor C2 are respectively electrically connected to the pixel transistor Tp and the power supply signal COM. In other embodiments, the second capacitor C2 can be electrically connected to the other power supply signal without being limited to the same power supply signal COM supplied to the first switching circuit 210.

The process of driving one pixel unit of the pixel circuits 120 (i.e., turning on the pixel transistor Tp to charge the second capacitor C2) includes a first charging period P1 and a second charging period P2. The voltage value on the node N3 of the pixel circuit 120 is between the low level L0 and the high level L255. In some embodiments, the voltage of the low level L0 corresponds to a gray level of 0, and the voltage of the high level L255 corresponds to a gray level of 255. That is, in the embodiment shown in FIG. 2, the first pixel unit in the pixel circuit 120 is controlled to the luminance of the gray scale 255, and the second pixel unit is controlled to the luminance of the gray scale 0.

Referring to FIG. 3A, in the first charging period P1, the first switching signal SW1 is an enable level, the second switching signal SW2 is a disable level, and the power supply signal COM is an enable level (e.g., low voltage, so that the second transistor switch T2 can be turned on), the first gate voltage Vg1 is the enable level. At this time, the first transistor switch T1 and the second transistor switch T2 are both turned on, and the third transistor switch T3 is turned off. Therefore, the data voltage Vd from the data line D will be applied to the first capacitor C1 and the pixel circuit 120, respectively, so that the voltage of the first terminal N1 (same as the node N3) is charged to the voltage of the data voltage Vd (e.g., 6 volts).

In the second charging period P2, the first switching signal SW1 is a disable level, the second switching signal SW2 is an enable level, and the power supply signal COM is a disable level (e.g., high voltage, the second transistor Switch T2 can not be turned on), the first gate voltage Vg1 is the enable level. At this time, the first transistor switch T1 and the second transistor switch T2 are all turned off, and the third transistor switch T3 is turned on. Since the two terminals of the third transistor switch T3 are electrically connected to the second terminal N2 of the first capacitor C1 N2 and the data line DL, the data voltage VL can be applied to the second terminal N2 of the first capacitor C1 through the third transistor switch T3 in the second switching circuit 220. According to the energy conservation law, the cross-voltage of the first capacitor C1 may maintain stable. Therefore, the voltage value of the terminal N1 of the first capacitor C1 will increase the amount of the data voltage Vd, and form twice the data voltage Vd, that is, the driving voltage Vb.

In some embodiments, the first transistor switch T1 and the second transistor switch T2 are connected in series. Therefore, when the first transistor switch T1 is turned on, the power supply signal COM is an enable level (e.g., low voltage) to turn on the second transistor switch T2. When the first transistor switch T1 is turned off, the power supply signal COM is the disable level (e.g., high voltage) to turn off the second transistor switch T2.

As mentioned above, in some embodiments, when the first switching circuit 210 is turned on, the second switching circuit 220 is turned off. When the second switching circuit 220 is turned on, the first switching circuit 210 is turned off. Since the first switching circuit 210 and the second switching circuit 220 are respectively turn on and turn off, the first capacitor C1 can be boosted, and the driving voltage Vb may be generated on the first terminal N1 of the first capacitor C1 (same as node N3).

In some embodiments, since the data voltage Vd is simultaneously applied to the first capacitor C1 and the second capacitor C2 in the pixel circuit 120 during the first charging period P1, the first terminal N1 of the first capacitor C1 may not be charged to the voltage of the data voltage Vd in the first charging period P1 according to the voltage division relationship between the plurality of capacitors. That is, the relative size relationship between the first capacitor C1 and the second capacitor C2 will affect the boosting amplitude of the boost circuit 200.

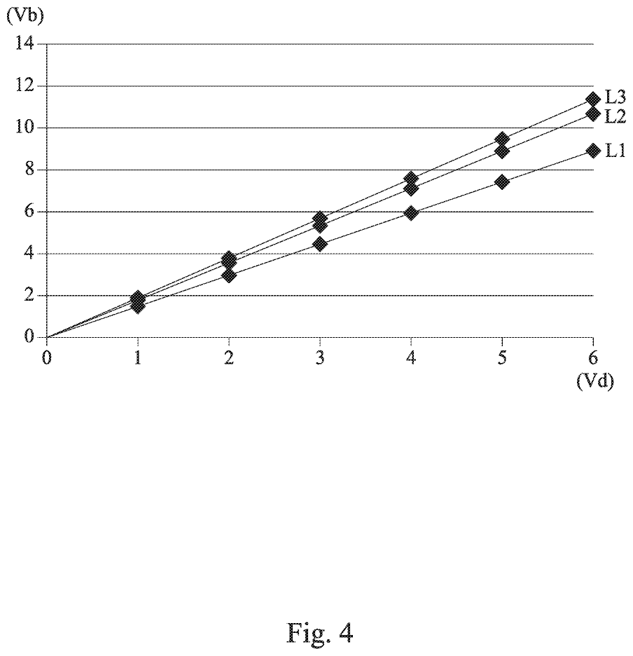

In some embodiments, the ratio of the capacitance of the first capacitor C1 to the capacitance of the second capacitor C2 is between 1:1 and 10:1. That is, the capacitance of the first capacitor C1 is between 1 and 10 times the capacitance of the second capacitor C2. Referring to FIG. 4, it is a schematic diagram of the driving voltage Vd according to some embodiments of the present disclosure. FIG. 4 shows three trend lines L1, L2, L3. The first trend line L1 represents the ratio of the first capacitor C1 to the second capacitor C2 is 1:1. The second trend line L2 represents the ratio of the first capacitor C1 to the second capacitor C2 is 4:1. The third trend line L3 represents the ratio of the first capacitor C1 to the second capacitor C2 is 10:1.

As shown in FIG. 4, when the ratio of the first capacitor C1 to the second capacitor C2 is 1:1, the boost circuit 200 boosts the data voltage Vd from 6 volts to about 8.2 volts. When the ratio of the first capacitor C1 to the second capacitor C2 is 4:1, the boost circuit 200 boosts the data voltage Vd from 6 volts to about 10.5 volts. When the ratio of the first capacitor C1 to the second capacitor C2 is 10:1, the boost circuit 200 boosts the data voltage Vd from 6 volts to about 11 volts. That is, the boosting amplitude of the boost circuit 200 is more obvious when the first capacitor C1 is larger. However, the larger the first capacitor C1 is, the larger the overall volume or area of the boost circuit 200 is. Therefore, the ratio of the first capacitor C1 to the second capacitor C2 is between 3:1 and 5:1. That is, the capacitance of the first capacitor C1 is between 3 and 5 times the capacitance of the second capacitor C2.

In addition, the boost circuit 200 is located on the display panel 100 corresponding to the position between the source driver 110 and the pixel circuit 120, but is located outside the display area (Active Area) where the pixel circuit 120 is located.

The components, method steps or technical features in the foregoing embodiments may be combined with each other, and are not limited by the description order or the drawing order in the present disclosure.

It will be apparent to those skilled in the art that various modifications and variations can be made to the structure of the present disclosure without departing from the scope or spirit of the present disclosure. In view of the foregoing, it is intended that the present disclosure cover modifications and variations of this present disclosure provided they fall within the scope of the following claims.

1. A display panel, comprising:
a boost circuit configured to receive a data voltage, and configured to generate a driving voltage according to the data voltage, wherein a voltage value of the driving voltage is greater than a voltage value of the data voltage, the boost circuit is configured to store the data voltage according to a first switching signal, and is configured to generate the driving voltage according to a second switching signal; and
a pixel circuit electrically connected to the boost circuit to receive the driving voltage; wherein the pixel circuit comprises a plurality of pixel units, each pixel unit of the plurality of pixel units comprises a pixel transistor and a second capacitor, the pixel transistor is turned on according to a gate voltage to charge the second capacitor, in a first charging period, the first switching signal is an enable level, the second switching signal is a disable level, and the gate voltage is the enable level; in a second charging period, the first switching signal is the disable level, the second switching signal is the enable level, and the gate voltage is the enable level.

2. (canceled)

3. The display panel of claim 1, wherein the boost circuit comprises a first capacitor, wherein when the boost circuit receives the first switching signal, a first terminal of the first capacitor is configured to receive the data voltage; when the boost circuit receives the second switching signal, a second terminal of the first capacitor is configured to receive the data voltage to generate the driving voltage on the first terminal of the first capacitor.

4. The display panel of claim 3, wherein the boost circuit further comprises:
a first switching circuit electrically connected to a data line, the first capacitor and the pixel circuit, wherein the first switching circuit is configured to turn on according to the first switching signal so that the data voltage is transmitted from the data line to the pixel circuit; and
a second switching circuit electrically connected to the data line and the first capacitor, wherein the second switching circuit is configured to turn on according to the second switching signal so that the driving voltage is generated on the first terminal of the first capacitor according to the data voltage.

5. The display panel of claim 4, wherein when the first switching circuit is turned on, the second switching circuit is turned off; when the first switching circuit is turned off, the second switching circuit is turned on.

6. The display panel of claim 5, wherein the first switching circuit comprises:
a first transistor switch electrically connected to the data line, the first terminal of the first capacitor and the pixel circuit; and
a second transistor switch electrically connected to the second terminal of the first capacitor and the power supply terminal to receive a power supply signal.

7. The display panel of claim 6, wherein when the first transistor switch is turned on, the power supply signal is an enable level to turn on the second transistor switch; when the first transistor switch is turned off, the power supply signal is a disable level to turn off the second transistor switch.

8. The display panel of claim 7, wherein the second switching circuit comprises:
a third transistor switch electrically connected to the second terminal of the first capacitor and the data line.

9. The display panel of claim 3, wherein a capacitance of the first capacitor is between 1 and 10 times a capacitance of the second capacitor.

10. The display panel of claim 9, wherein the capacitance of the first capacitor is between 3 and 5 times the capacitance of the second capacitor.

11. A boost circuit, comprising:
a first switching circuit electrically connected to a data line and a pixel circuit to receive a data voltage, wherein the first switching circuit is configured to turn on according to a first switching signal;
a first capacitor, a first terminal of the first capacitor electrically connected to the first switching circuit; and
a second switching circuit electrically connected to the data line and a second terminal of the first capacitor to generate a driving voltage according to the data voltage, wherein a voltage value of the driving voltage is greater than a voltage value of the data voltage, the second switching circuit is configured to turn on according to a second switching signal;
wherein the pixel circuit comprises a plurality of pixel units, each pixel unit of the plurality of pixel units comprises a pixel transistor and a second capacitor, the pixel transistor is turned on according to a gate voltage to charge the second capacitor, in a first charging period, the first switching signal is an enable level, the second switching signal is a disable level, and the gate voltage is the enable level; in a second charging period, the first switching signal is the disable level, the second switching signal is the enable level, and the gate voltage is the enable level.

12. The boost circuit of claim 11, wherein the first switching circuit is configured to turn on according to the first switching signal so that the data voltage is transmitted from the data line to the pixel circuit; and
the second switching circuit is configured to turn on according to the second switching signal so that the driving voltage is generated on the first terminal of the first capacitor according to the data voltage.

13. The boost circuit of claim 12, wherein when the first switching circuit is turned on, the second switching circuit is turned off; when the first switching circuit is turned off, the second switching circuit is turned on.

14. The boost circuit of claim 13, wherein the first switching circuit comprises:
a first transistor switch electrically connected to the data line, the first terminal of the first capacitor and the pixel circuit; and
a second transistor switch electrically connected to the second terminal of the first capacitor and the power supply terminal to receive a power supply signal.

15. The boost circuit of claim 14, wherein when the first transistor switch is turned on, the power supply signal is an enable level to turn on the second transistor switch; when the first transistor switch is turned off, the power supply signal is a disable level to turn off the second transistor switch.

16. The boost circuit of claim 15, wherein the second switching circuit comprises:
a third transistor switch electrically connected to the second terminal of the first capacitor and the data line.
